(19) United States
(12) Patent Application Publication
(10) Pub. No.: US 2003/0005886 A1
(43) Pub. Date: Jan. 9, 2003

(54) Horizontal reactor for compound semiconductor growth

(76) Inventors: Keunseop Park, Daejeon (KR); Seung-Jae Nam, Daejeon (KR); Cheul-Ro Lee, Jeonju-si (KR); Byung-Joon Baek, Jeonju-si (KR)

Correspondence Address: BAKER & BOTTS, 30 ROCKEFELLER PLAZA, NEW YORK, NY, 10112

(21) Appl. No.: 10/150,462

(22) Filed: May 17, 2002

(30) Foreign Application Priority Data
May 17, 2001 (KR) 2001-26888

(51) Int. Cl. C23C 16/00

(52) U.S. Cl. 118/725

(57) ABSTRACT

A horizontal reactor for processing an elemental compound semiconductor growth is provided with a reactor housing having a sealed container, a susceptor with an upper surface provided with a plurality of substrate mounts which receive substrates, the upper surface positioned inside the reactor housing, a heater for heating the susceptor, a Group V gaseous material supply in a vertically upward direction from a lower center of the susceptor, and a Group III gaseous material supply with delivery gas in a vertically downward direction toward a center of the upper surface of the susceptor, wherein the Group III gaseous material and the Group V gaseous material form a reaction gas when mixed together and the horizontal reactor is further provided with a remaining reaction gas exhaust after contribution to the semiconductor growth.

### FIELD OF THE INVENTION

The present invention relates to a reactor for processing semiconductors and, in particular, to a horizontal reactor having a large processing area for processing Group III-V compound semiconductors.

### BACKGROUND OF THE INVENTION

Compound semiconductor devices will be featured in equipment of the upcoming, information-oriented society, such as hardware with high-speed, greater capacity, more visualized interfaces, etc., and are presently manufactured using an epitaxial-growth method.

Compound semiconductor products have been used in emitting diodes for displays, optical telecommunication equipment, laser diodes (LD) for compact/video discs (CD/VD), photoconductors, capacitors for high-speed computers, capacitors for satellites, and the like. The use of compound semiconductor products is being extended to mobile telecommunications equipment, blue laser diodes for optical digital displays (ODD), capacitors for optical computers, and the like.

Among these, blue LED is manufactured from Group III-V nitrides such as AlN, GaN, InN, and the like, and has emitting wavelengths of about 450 nm. Metal Organic Chemical Vapor Deposition (MOCVD) systems are generally used in processing Group III-V nitride semiconductors. MOCVD systems are divided into two basic groups based on the reactor types, i.e. horizontal reactors and vertical reactors.

In an epitaxial-growth of a Group III-V compound semiconductor using the MOCVD system, metal organic in liquid state is generally employed as a Group III raw material to be supplied to the reactor by a delivery gas. Group V raw material is supplied to the reactor normally in its gaseous state or in a state diluted with the delivery gas. At the moment, one of the factors needed for good epitaxial film growth is to control reaction gases in such a manner that a laminar flow of the reaction gases is formed over a substrate in a parallel relationship therewith.

In a vertical reactor, in order to obtain such laminar flow of the reaction gases, a showerhead and a susceptor have to be positioned close to each other and the susceptor on which the substrates are placed is required to be rotated at a high rotational speed (e.g. from hundreds RPM to thousands RPM). On the other hand, in the horizontal reactor, it is easy to form the laminar flow of the reaction gases because the reaction gases flow on the substrate in a relatively parallel relationship with the substrate. For this reason, it is more advantageous to use the horizontal reactor than the vertical reactor in an epitaxial film growth for improved uniformity. However, the horizontal reactor has a shortcoming that it is difficult to perform an epitaxial growth over a large processing area by using the horizontal reactor.

Prior art publications for processing Group III-V compound semiconductors include U.S. Pat. No. 5,433,169 issued to Nakamura et al. and EP Patent Publication No. 0687749A1, etc.

### SUMMARY OF THE INVENTION

It is, therefore, an object of the present invention to provide an improved horizontal reactor for processing Group III-V compound semiconductors, wherein a laminar flow of reaction gases can be easily formed and a uniform epitaxial growth is provided over a large processing area.

The present invention is a horizontal reactor for processing compound semiconductor growth. It is comprised of a reactor housing having a sealed container, and a susceptor having its upper surface provided with a plurality of substrate mounts for receiving substrates thereon. The upper surface the susceptor is positioned inside the reactor housing, a heater for heating the susceptor is also provided along with a Group V gas supply for supplying Group V gaseous material in a vertically upward direction from the lower center of the susceptor. Also provided is a Group III gas supply for supplying Group III gaseous material and a delivery gas for delivering the gaseous material in a vertically downward direction toward the center of the upper surface of the susceptor. The horizontal reactor is further provided with a remaining reaction gas exhaust for exhausting any remaining reaction gas out of the reactor housing after contribution to the compound semi-conductor growth.

### BRIEF DESCRIPTION OF DRAWINGS

FIG. 1 illustrates a frontal schematic view of a preferred embodiment of the inventive horizontal reactor.

FIG. 2 depicts a top planar view of a susceptor employed in the inventive horizontal reactor.

### DETAILED DESCRIPTION OF THE PRESENT INVENTION

Preferred embodiments of the present invention will now be described with reference to the accompanying drawings.

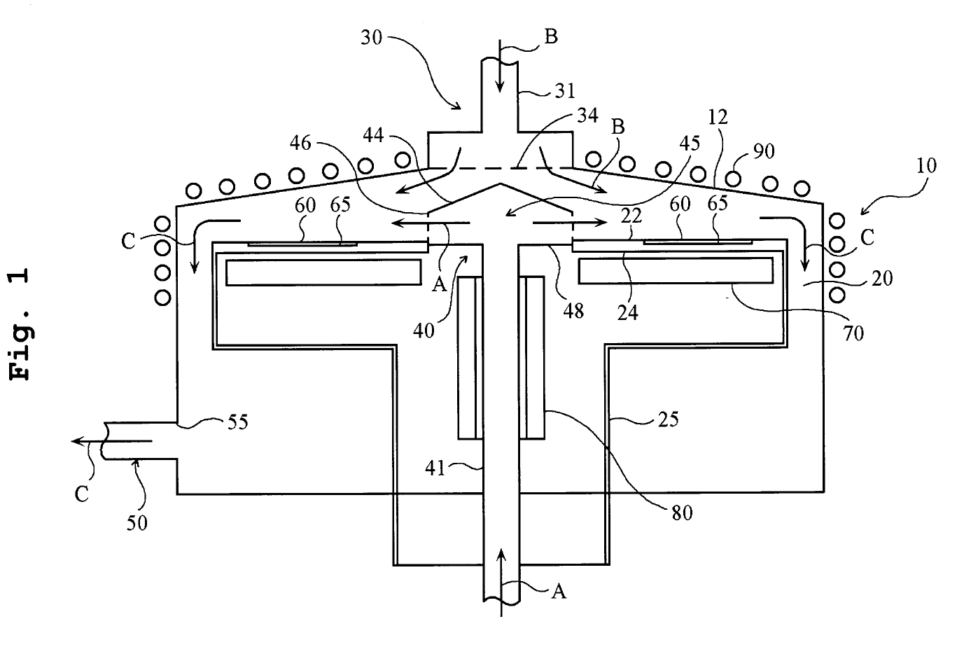

FIG. 1 shows a schematic view of a preferred embodiment of a large processing area horizontal reactor for processing compound semiconductors in accordance with the present invention. Although the inventive horizontal reactor is mainly used for a process of MOCVD (metal organic chemical vapor deposition) for manufacturing the compound semiconductor as disclosed herein, it may be used for other processes for manufacturing the compound semiconductor. Such alternative applications will become apparent to those skilled in the art after having the benefit of this disclosure.

The horizontal reactor 1 shown in FIG. 1 is provided with a reactor housing 10 of a sealed container shape, a susceptor 20 adapted to receive a plurality of substrates 60 on which a semiconductor film is formed, a heater 70 for heating substrates 60 on the susceptor 20, a Group V gas supply 40 for supplying Group V gaseous material A, a Group III gas supply 30 for supplying Group III gaseous material and a delivery gas for delivering the Group III gaseous material B, and a reaction gas exhaust 50 for exhausting the remainder of a reaction gas C including the Group III gaseous material and the delivery gas B and the Group V gaseous material A after a contribution of the reaction gas C to the epitaxial film growth.

As shown in FIG. 1, the reactor housing 10 of the sealed container shape has the susceptor 20 therewithin. An upper plate 12 of the reactor housing 10 serves to guide a laminar flow of the reaction gas C, cooperating with an upper surface 22 of the susceptor 20 and covers an entire area of the upper surface 22 of the susceptor 20. In a central area of the upper plate 12 of the reactor housing 10, an outlet of the Group III gas supply 30 is formed to communicate with an inside of the reactor housing 10. Further, an exhausting opening 55 through which the reaction gas C remaining after contribution to the semiconductor film growth is exhausted to the outside is formed through a flank portion of the reactor housing 10 and a passage through which the reaction gas C flows is formed between a lateral surface of the susceptor 20 and an inner surface of the flank portion of the reactor housing 10.

A lower plate of the reactor housing 10 shuts off a lower portion of the reactor housing 10 which receives a Group V gas supply tube 41 through which the Group V gaseous material A is guided into the inside of the reactor housing 1, and a susceptor rotator 25 for rotating the susceptor 20 is also provided therein, thereby keeping the reactor housing 10 in a hermetic state.

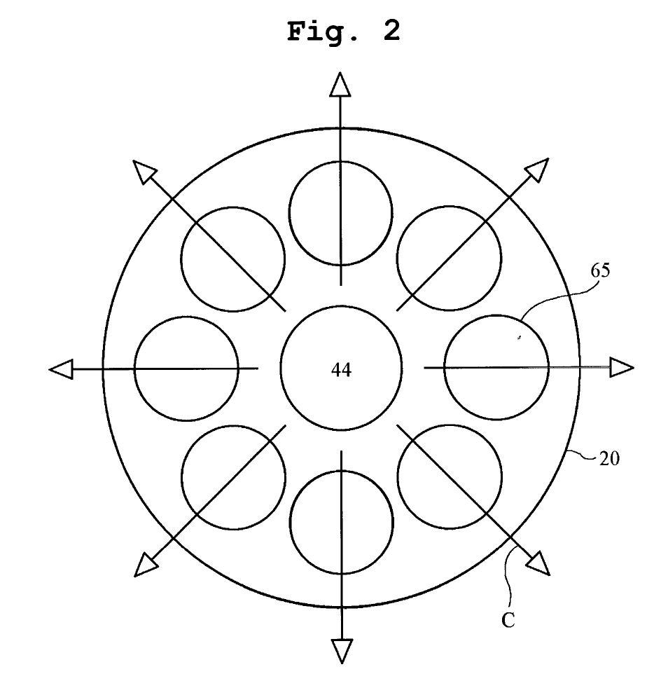

As shown in FIG. 2, the susceptor 20 has a plurality of substrate mounts 65 which receive thereon a plurality of substrates 60 on which semiconductors are formed and grow. The substrate mounts 65 are arranged along a circumference of the susceptor 20. Further, an outlet of the Group V gas supply 40 supplying the Group V gaseous material A is formed through a center of the susceptor 20.

It is preferable that the susceptor rotator 25 be formed to downwardly extend from a lower surface of the susceptor 20 in order to rotate the susceptor 20. Further, the susceptor 20 and the susceptor rotator 25 may be formed as separate components from each other. The susceptor rotator 25 can be rotated by a separate driving means. The rotation of the susceptor rotator 25 and the susceptor 20 enable a uniform epitaxial growth on the plurality of substrates 60 arranged along the circumference of the susceptor 20 in a same distance from the center of the susceptor 20. Further, a power supply wire connected to the heater 70 for heating the susceptor 20, a temperature sensor for measuring a temperature of the gas or the like, may be provided in an inner space of the susceptor rotator 25.

The Group V gas supply 40 includes the Group V gas supply tube 41 which guides the Group V gaseous material A from a gas source outside the horizontal reactor 1 into the inside of the reactor housing 10. The outlet of the Group V gas supply tube 41 is formed through the center of the susceptor to extend up to the upper surface 22 of the susceptor 20, and at which the Group V gaseous material A emits upwardly. The Group V gaseous material A supplied through the center of the susceptor 20 is mixed with the Group III gaseous material with delivery gas B and, then the mixed gaseous material A and B forms a reaction gas C, which moves in a radially outward direction of the susceptor 20, forming a laminar flow through a passage formed between an inner surface of the upper plate 12 of the reactor housing 10 and the upper surface 22 of the susceptor 20.

The Group III gas supply 30 includes the Group III gas supply tube 31 which guides the Group III gaseous material and the delivery gas B from a gas source outside the horizontal reactor 1 into the inside of the reactor housing 10. An outlet of the Group III gas supply tube 31 is formed through the upper plate 12 of the reactor housing 10. The Group III gaseous material and the delivery gas B supplied through the Group III gas supply tube 31 is mixed with the Group V gaseous material before they arrive at an area of the substrates 60, to form the reaction gas C.

It is preferable that a position of the outlet of the Group III gas supply 30 corresponds to that of the outlet of the Group V gas supply 40.

As shown in FIG. 1, a portion of the upper plate 12 of the reactor housing 10 with the exception of the outlet for the Group III gas supply 30 positioned on the center of the upper plate 12, is slanted so that it has a declining height along the radially outward direction of the reactor housing 10 from the center thereof. With this configuration, it is possible to prevent the reaction gas C from being agitated upward by the heat while the reaction gas C flows in the radially outward direction from the center of the reactor housing 10. As the cross-sectional area of the passage formed by the upper plate 12 and the upper surface 22 of the susceptor 20 becomes lower along the radially outward direction of the susceptor 20, it is further possible to prevent a reduction problem of concentration of the reaction gas C that would otherwise become serious at places far from the center of the susceptor 20 in the radial direction thereof.

It is more preferable that a vertical showerhead 34 having a plurality of holes with same separation therebetween through which the Group III gaseous material and the delivery gas B pass, be formed near the outlet of the Group III gas supply 30. With this, a vortex flow of the reaction gas C that may be formed can be avoided and it is possible to form a more stabilized laminar flow of the reaction gas C.

In order to avoid adherence of byproducts to the inner surface of the upper plate 12 of the reactor housing 10 that may be caused by the heat transferred from the susceptor 20, the upper plate 12 may be cooled by water supplied through a water jacket 90. Further, a leading portion of a high temperature measurement sensor for detecting a temperature of the substrate 60 may be positioned on the upper plate 12 of the reactor housing 10.

It is more preferable that a flow guider 45 for radially and outwardly guiding the flow of the Group V gaseous material A supplied through the Group V gas supply 40, be formed at the outlet of the Group V gas supply 40. The flow guider 45 is a form of a cylindrical chamber positioned in coaxial relationship with a central axis of the susceptor 20, and includes a guide cap 44, a lower end 48 communicating with the outlet of the Group V gas supply 40, and a lateral wall formed between the guide cap 44 and the lower end 48 and having a horizontal showerhead 46 provided with a plurality of holes with a same separation therebetween.

With this configuration, it is possible to prevent a vortex flow that may occur when the Group V gaseous material A and the Group III gaseous material with the delivery gas B collide with each other.

The Group V gaseous material A supplied vertically is changed in flow direction by an inner surface of the guide cap 44 of the flow guider 45 into the radially outward direction of the susceptor 20 and then flows through the horizontal showerhead 46 formed through the lateral wall. Accordingly, although a vortex flow of the Group V gaseous material A may occur when the Group V gaseous material A supplied at the outlet of the Group V gas supply 40 collides against inner surfaces of the cylindrical chamber, the vortex flow is changed into the laminar flow as it is passed through the horizontal showerhead 46.

The guide cap 44 further guides the Group III gaseous material and the delivery gas B at its external surface, so that the Group III gaseous material and the delivery gas B is guided in the radially outward direction, complying with the inner surface of the upper plate 12 of the reactor housing 10. As a result, a more stabilized laminar flow of the Group III gaseous material and the delivery gas B is obtained and hence a more stabilized reaction gas C of the laminar flow is formed, enabling more uniform epitaxial growth of the semiconductor. Further, this allows the Group III gaseous material B and the Group V gaseous material A to be mixed together to form the reaction gas C in an area closer to the substrate 60, whereby the loss of the raw material, e.g. the adherence of the byproducts to the inner surface of the upper plate 12 that may occur due to an earlier generation of the reaction gas C in an area far from the substrate 60, i.e. closer to the center of the susceptor 20, can be reduced.

The Group V gaseous material A and the Group III gaseous material and the delivery gas B supplied from an upper center and a lower center of the reactor housing 10, respectively, firstly flow independently in the form of the laminar flow, and then are contacted with each other to be mixed, maintaining the laminar flow state thereof. With this configuration, uniform epitaxial film growth is performed with respect to all of the substrates 60 arranged on the upper surface 12 of the susceptor 20 along the circumference thereof

It is preferable that the guide cap 44 of the flow guider 45 be formed in a substantial conical shape, as shown in FIG. 1. The conical shape prevents the vortex flow that may occur when the Group III gaseous material and the delivery gas B collide on the guide cap 44 and naturally changes the flow direction of the Group III gaseous material and the delivery gas B to a direction parallel with the substrate 60.

The heater 70 is installed in the inside of the susceptor 20 to face a lower surface 24 of the susceptor 20, adjacent thereto and serves to heat the susceptor 20. As a result, the plurality of substrates 60 resting on the upper surface 22 of the susceptor 20 are heated at the same time.

It is preferable that the inventive horizontal reactor 10 be further provided with a Group V gas pre-heater 80 for pre heating the Group V gaseous material A for its thermal decomposition before the Group V gaseous material A arrives at the substrate 60.

Table 1, below, represents optimal growth conditions and results of a test of the GaN epitaxial growth by using an MOCVD reactor in two cases where ammonia supplied as source material of nitrogen is prior heated for the thermal decomposition and where the ammonia is not subjected to the thermal decomposition, respectively. The reactor used in the test is a device in accordance with Korean Patent No. 0271831.

As shown, the case where the ammonia is previously subjected to the thermal decomposition shows a higher growth-speed in spite of a lower amount of the raw material supplied. The amount of the raw material used in growing a certain magnitude of the film thickness when thermal decomposition is performed, is lower than the alternative with no thermal decomposition. The thermal decomposition not only helps the reduction of the processing time but also enables a superior quality of epitaxial film according to the results of the measurement using the Hall Effect.

TABLE 1
[Optimal growth conditions and results in the MOCVD device]

| | NH₃ is thermally | | NH₃ is not thermally | |
|---|---|---|---|---|
| | decomposed before being | | decomposed before being | |
| | supplied to the susceptor | | supplied to the susceptor | |
| Supply amount of | 70 | μmol/min | 110 | μmol/min |
| TMGa | | | | |
| Supply amount of | 70 | mmol/min | 160 | mmol/min |
| NH₃ | | | | |
| Film growth speed | 50 | nm/min | 23 | nm/min |
| of GaN | | | | |
| Amount of TMGa | 3.5 | mmol | 9.6 | mmol |
| used in growing | | | | |
| GaN film of 2 μm | | | | |
| thickness | | | | |
| Amount of NH₃ | 3.5 | mol | 14 | mol |
| used in growing | | | | |
| GaN film of 2 μm | | | | |
| thickness | | | | |
| Mobility | 670 | cm³/Vs | 540 | cm³/Vs |
| Back doping | 3 × 10¹⁶ | cm⁻³ | 9 × 10¹⁶ | cm⁻³ |

In the embodiment described above, although the flow guider 45 is configured to have the guide cap 44, the lower end 48 and the Group V gas supply tube 41 all integrally formed with one another, the horizontal showerhead 46 and the guide cap 44 may be formed as separate components. With this configuration, the guide cap 44 on which the byproducts may accumulate, can be easily washed.

The inventive horizontal reactor for processing the compound semiconductors constructed in this manner, provides a reactor for processing Group III-V compound semiconductors capable of keeping the reaction gas in the laminar flow and of performing the uniform epitaxial growth of the semiconductors over a large processing area.

While the present invention has been shown and described with respect to the particular embodiments, it will be apparent to those skilled in the art that many adaptations and modifications may be made without departing from the spirit and scope of the invention as defined in the appended claims.

What is claimed is:

1. A horizontal reactor for processing compound semiconductor growth, comprising:
a reactor housing having a sealed container;
a susceptor having its upper surface provided with a plurality of substrate mounts receiving substrates thereon, the upper surface being positioned inside the reactor housing;
a heating means for heating the susceptor;
a Group V gas supplying means for supplying Group V gaseous material in a vertically upward direction from a lower center of the susceptor;
a Group III gas supplying means for supplying Group III gaseous material and a delivery gas therefore, in a direction opposite to that of the Group V gaseous material toward a center of the upper surface of the susceptor, the Group III gaseous material and the Group V gaseous material forming a reaction gas when they are mixed together; and
a remaining reaction gas exhausting means for exhausting remaining reaction gas out of the reactor housing after contribution to the compound semiconductor growth.

2. The horizontal reactor of claim 1, wherein said Group III gas supplying means has its outlet positioned to correspond to a position of an outlet of the Group V gas supplying means.

3. The horizontal reactor of claim 1, further comprising a flow guiding means for guiding flow of the Group V gaseous material and the Group III gaseous material and the delivery gas therefor, into a radially outward direction of the susceptor along the upper surface of the susceptor.

4. The horizontal reactor of claim 3, wherein the flow guiding means further comprises:
a guide cap having a conical shape with its apex pointing in an upward direction and positioned below an outlet of the Group III gas supplying means;
a lower end communicating with an outlet of the Group V gas supplying means; and
a lateral wall formed between the guide cap and the lower end and having a horizontal showerhead provided with a plurality of holes with the same separation distance therebetween.

5. The horizontal reactor of claim 4, wherein the flow guiding means further comprises a vertical showerhead positioned at the outlet of the Group III gas supplying means and having a plurality of holes through which the Group III gaseous material and the delivery gas therefor pass.

6. The horizontal reactor of claim 1, wherein the reactor housing has an upper plate shaped to be so that it has a declining height along the radially outward direction of the reactor housing from the center thereof.

7. The horizontal reactor of claim 2, wherein the reactor housing has an upper plate shaped to be so that it has a declining height along the radially outward direction of the reactor housing from the center thereof.

8. The horizontal reactor of claim 3, wherein the reactor housing has an upper plate shaped to be so that it has a declining height along the radially outward direction of the reactor housing from the center thereof.

9. The horizontal reactor of claim 1, further comprising a Group V gas pre-heater for prior heating the Group V gaseous material for thermal decomposition before the Group V gaseous material A arrives at the substrate.

10. The horizontal reactor of claim 2, further comprising a Group V gas pre-heater for prior heating the Group V gaseous material for thermal decomposition before the Group V gaseous material A arrives at the substrate.

11. The horizontal reactor of claim 3, further comprising a Group V gas pre-heater for prior heating the Group V gaseous material for thermal decomposition before the Group V gaseous material A arrives at the substrate.

12. The horizontal reactor of claim 1, further comprising a susceptor rotator for rotating the susceptor.

13. The horizontal reactor of claim 2, further comprising a susceptor rotator for rotating the susceptor.

14. The horizontal reactor of claim 3, further comprising a susceptor rotator for rotating the susceptor.

15. The horizontal reactor of claim 1, wherein said Group III gaseous material and said Group V gaseous material are mixed with each other to form the reaction gas before they arrive at the substrates.

16. The horizontal reactor of claim 2, wherein said Group III gaseous material and said Group V gaseous material are mixed with each other to form the reaction gas before they arrive at the substrates.

17. The horizontal reactor of claim 3, wherein said Group III gaseous material and said Group V gaseous material are mixed with each other to form the reaction gas before they arrive at the substrates.
